(19) United States
(12) Patent Application Publication
(10) Pub. No.: US 2014/0327098 A1
(43) Pub. Date: Nov. 6, 2014

(54) METHOD OF PRODUCING A RADIATION IMAGER EXHIBITING IMPROVED DETECTION EFFICIENCY

(71) Applicant: COMMISSARIAT A L'ENERGIE ATOMIQUE ET AUX ENE ALT, Paris (FR)

(72) Inventors: Eric Gros D'Aillon, Vourey (FR); Luc Andre, Grenoble (FR); Vincent Reboud, Paris (FR)

(73) Assignee: COMMISSARIAT A L'ENERGIE ATOMIQUE ET AUX ENE ALT, Paris (FR)

(21) Appl. No.: 14/365,282

(22) PCT Filed: Dec. 14, 2012
(86) PCT No.: PCT/EP12/75662

§ 371 Date: Jun. 13, 2014

(30) Foreign Application Priority Data
Dec. 14, 2011 (FR) 11 61645

(51) Int. Cl. H01L 27/146

(52) U.S. Cl. CPC H01L 27/14685; H01L 27/14659; H01L 27/14663
USPC 257/428; 438/65

(57) ABSTRACT

A radiation imager including: a reading block; a first substrate; a plurality of portions made from a first material with a first optical index between the first substrate and the reading block; a second material at a periphery of at least one of the portions, the second material having a second optical index lower than the first optical index; and areas made from a third material surrounding at least ends of the portions oriented on a same side as the reading block, the areas made from a third material obtained by applying a layer made from a third material to the reading block and penetration of the end of the at least one portion made from a first material in the layer made from a third material.

### TECHNICAL FIELD AND PRIOR ART

The present invention concerns the field of radiation imagers, for example for ionising radiation.

Ionising radiation imagers are intended to detect ionising radiation, such as for example X or gamma rays. One type of ionising radiation imager uses a scintillator, also referred to as a “detector”, which converts the ionising radiation into visible radiation. It is this visible radiation that is then detected by photodetectors disposed downstream of the scintillator in the direction of propagation of the radiation. Photodetectors are generally divided into matrices.

Photodetectors may be of the CMOS (“Complementary Metal Oxide Semiconductor”) type. Each photodetector comprises an active part, which serves to detect the light radiation forming the signal, and electronic means. The whole forms the reading block. Electronic means are assembled in the immediate vicinity of the photodetectors and are attached to the sides.

The scintillator is disposed on a transparent substrate that forms a mechanical support for it; this substrate is chosen so as to be transparent to visible radiation. This assembly, referred as the detector block, is situated above the photodetectors.

The reading block and the detection block are separated by a layer of air. However, the effect of this layer of air is that a measured part of the visible radiation is trapped in the detector block. The detection efficiency is therefore very low.

For example, in the case where the scintillator has an optical index equal to 1.82, 92% of the visible radiation is trapped in the detector block.

The document WO 2009/024895 describes a radiation detector comprising light concentrators between a scintillator and a light-sensitive area.

### DISCLOSURE OF THE INVENTION

Consequently one aim of the present invention is to offer a method for producing a radiation imager with improved detection efficiency and a radiation imager with improved detection efficiency.

The aim stated above is achieved by a radiation imager and a method for producing said imager, the imager comprising a substrate and a reading block formed by several photodetectors, the photodetectors being disposed at a distance from the substrate, and light guides disposed between the substrate and one or more photodetectors in order to capture the visible photons of the radiation and to bring them to the photodetectors, the waveguides being formed by portions made from a first material transparent to visible radiation having a first optical index connecting the substrate to N photodetectors, and a second material having a second optical index lower than the first optical index or being a reflective material, said second material at least partly surrounding one of the portions made from the first material. The waveguides are produced directly on a substrate by photolithography or by imprinting. Prior to the assembly of the substrate and the reading block, a layer made from a third material is deposited on the reading block so that said layer of third material wets the free ends of the waveguides made from a first material during assembly, thus forming rectifiers.

By means of the invention, the guiding structures collect more photons by virtue of the beam rectifiers added at the foot of the waveguides.

The invention therefore increases the detection efficiency. It may also increase the spatial resolution by guiding the visible photons to the photodetector or photodetectors closest to the generation area thereof in the detector block. The spatial precision of the image thus obtained is therefore improved.

Advantageously, the first material of the waveguides is formed by an adhesive, for example a glue, also serving to fix together the detector block and the reading block. The second material is advantageously air.

Highly advantageously, the first material is structured so that the transverse section thereof reduces from the detection block towards the photodetector or photodetectors.

The subject matter of the present invention is then a method for producing a radiation imager comprising a reading block intended to convert the radiation into an electrical signal, comprising a plurality of photodetectors, said method comprising the steps of:

a) forming a plurality of portions of a first material, with a first index, on a first substrate, the portions comprising, at the periphery thereof, a second material, said second material having a second optical index lower than the first optical index or being a reflective material,

b) forming a flat layer made from a third material on said reading block,

c) aligning the first substrate with respect to the reading block, so that said portions formed on the detector block are disposed opposite the photodetectors of the reading block,

d) assembling said substrate and said reading block by means of the portions made from a first material, so that the third material is wetted on said portions of the first substrate,

e) hardening the third material.

In one embodiment, step a) comprises:
the formation of a layer made from a first material on the first substrate, the first material being a resin,
the placing of a mould provided with cavities having the external shape of the portions made from a first material above the layer made from a first material,
the pressing of the first material by the mould,
the heating of the first material above the glass transition temperature of the first material,
the cooling of the first material below said glass transition temperature, and then removal from the mould.

In another embodiment, step a) comprises:
the formation of a layer of the first material on the first substrate, the first material being a resin,
the insolation of the first material through a mask defining the portions made from the first material,
activation of the polymerisation by low-temperature annealing,
removal of the parts of the first material that were insolated.

Preferably, during step b), the thickness of the layer made from a third material is between h/10 and 3/h/4, h being the height of the portions made from the first material. For example, the thickness of the layer from the third material is between 100 nm and 3 μm.

Preferably, the optical index of the third material is greater than or equal to that of the second material.

The first material is an SU8 resin or a resin of the Epotek353ND, Epotek360ND or polycarbonate type.

The first material advantageously has an index close to that of the material of the detector, preferably between 1.4 and 3.

For example, the cavities of the mould have a shape of revolution or polygonal. The cavities of the mould have a variable cross-section reducing as from the face wherein they emerge.

Preferably, the mould and the substrate comprising the layer of resin are heated before the pressing step.

The first substrate is advantageously a transparent material, for example glass.

In an example embodiment, the method may comprise the additional step of producing the detector block on said substrate, after assembly of the substrate and reading block.

In another example embodiment, the first substrate is a detector block having a detector block, comprising at least one detector able to emit an optical signal from an incident radiation to be imaged.

The method may comprise a step of surface treatment of said portion so as to modify the surface energy thereof.

The layer of the first material can be deposited by centrifugal coating.

The manufacturing method comprises for example a step of producing a via by means of metal balls.

### BRIEF DESCRIPTION OF THE DRAWINGS

The present invention will be better understood by means of the following description and the accompanying drawings, on which:

FIG. 1 is a side view of a first embodiment of a radiation imager according to the invention produced in accordance with a method according to the invention,

FIGS. 2A and 2B are perspective and plan views of a matrix of pixels provided with light guides used in the imager of FIG. 1,

FIGS. 3A and 3B are perspective and plan views of a pixel of the matrix of FIGS. 2A and 2B,

FIG. 4 is a perspective view of a second embodiment of a pixel provided with several light guides,

FIG. 5 is a schematic representation of the travel of the visible radiation in a light guide of FIG. 4,

FIGS. 6A and 6B are perspective views of another example embodiment of the light guide of FIG. 4,

FIGS. 7A and 7B are perspective views of another example in perspective of another example embodiment of the light guide in FIG. 4,

FIG. 8 is a graphical representation of the portion of light collected according to the angle of incidence for various pixels,

FIGS. 9A to 9H are schematic representations of various steps of implementation of a production method according to one embodiment of the invention,

FIGS. 10A and 10B are detail views of steps of the method illustrated by FIGS. 9A to 9H,

FIGS. 11A, 11B and 11C are enlarged schematic representations of FIGS. 10A and 10B,

FIGS. 12A and 12B are schematic representations of a variant of the method according to the invention,

FIGS. 13A and 13B are schematic representations of various forms of light-guide pads that can be used in the present invention and can be obtained by photolithography,

FIG. 14 is a photograph of a pad surrounded by an area of resin at the end thereof in contact with the reading block obtained by virtue of the method according to the invention.

### DETAILED DISCLOSURE OF PARTICULAR EMBODIMENTS

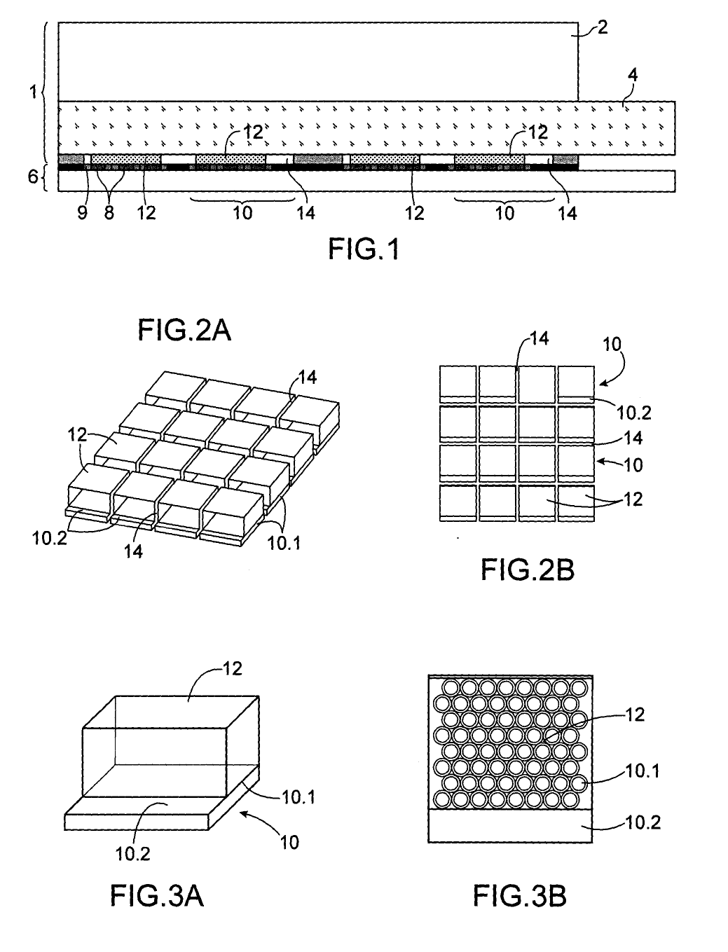

In FIG. 1, an example of an ionising radiation imager according to the invention can be seen, depicted schematically, this imager being produced by a method according to the present invention.

The imager comprises a detector block 1 that is formed in the example shown by a scintillator 2 and a substrate 4 transparent to visible radiation, for example made from glass on which the detector is deposited, and a reading block 6, disposed at a distance from the substrate 4 opposite to the detector 2. The detector converts the ionising photons into visible photons.

The substrate 4 provides the rigidity of the detector, in particular when the latter is thin. The substrate may however be omitted in the case where the thickness of the detector 2 is sufficient to ensure its own rigidity.

The reading block 6 comprises a plurality of photodetectors 8; in the example shown, these are advantageously distributed in one plane. The photodetectors are for example avalanche photodiodes, for example SPADs (Single Photon Avalanche Diodes), or simple photodiodes.

The photodetectors 8 are, in our example, SPAD photodetectors disposed at a distance from one another and separated by a guard ring 9. The photodetectors are grouped together in pixels.

Each pixel 10 has electronics. The pixels 10 are, themselves, disposed in a matrix. In FIGS. 2A and 2B, a matrix of pixels 10 can be seen. In FIGS. 3A and 3B, a single pixel can be seen. The pixel comprises an active part 10.1 that detects the light radiation coming from the detector block and an electronic part 10.2 disposed on one side of the active part at 10.1.

The imager also comprises portions made from a first material 12 disposed between the detection block and the reading block, each portion made from a first material 12 optically connecting the substrate 4 and one or more photodetectors.

The portions of first material 12 are separated from one another by a second material 11, the optical index of which is lower than that of the first material. In the example shown in FIGS. 1, 2A, 2B and 3A and 3B, the portions 12 of first material each cover a pixel and are in the form of a right-angled parallelepiped comprising a face 12.1 in contact with the active part 10.1 of the pixel and leaving the electronic part 10.2 uncovered, and a face 12.2 parallel to the face 12.1 in contact with the substrate 4. Furthermore, the portions made from a first material 12 are separated from one another by a gas, for example air, which simplifies the manufacture.

The portions of material covering several photodetectors also have the advantage of improving the mechanical strength of the structure.

The first material has an optical index close to that of the material of the substrate 4 and of the detector. Preferably the optical index of the first material is between 1.4 and 3.

The end of each portion 12 in contact with the reading block is surrounded by an area 14 made from a third material forming a rectifier. This third material is advantageously a glue or a resin. The area 14 is also referred to as the “foot”. The third material has an optical index preferably greater than or equal to that of the second material, further amplifying the effect of rectifying the radiation.

This area 14 around each pad 12 forms an area for rectifying beams towards the photodetection area. The active detection area is in general buried several micrometres under the surface with several levels of metal of electrical connections on the sides of the detection area, shown schematically by broken lines and FIGS. 11A and 11B. The area 14 rectifies the light beams coming from the scintillator towards the detection area, avoiding these metal levels. In the absence of this rectifying area, the light beams have a tendency to settle down after one or more reflections in the waveguides, i.e. they are more and more parallel to the surfaces of the photodetectors, their angle of incidence in the waveguides increasing as the detection areas are approached.

The presence of these rectifying areas at the contact between the waveguide pads and the photodetectors is all the more advantageous since the silicon has high reflection at high angles. By virtue of the rectification of the incident beams in the waveguides, the entry thereof is promoted towards the detection areas.

Advantageously, the first material is an adhesive material, for example a resin used in microelectronic processes. As will be seen hereinafter, the use of resin is particularly advantageous for producing these waveguides since it is commonly used in microelectronic processes, but for other purposes.

In FIG. 3B, the array of photodetectors 8 with the guard rings can be seen by transparency, this array forming the active part.

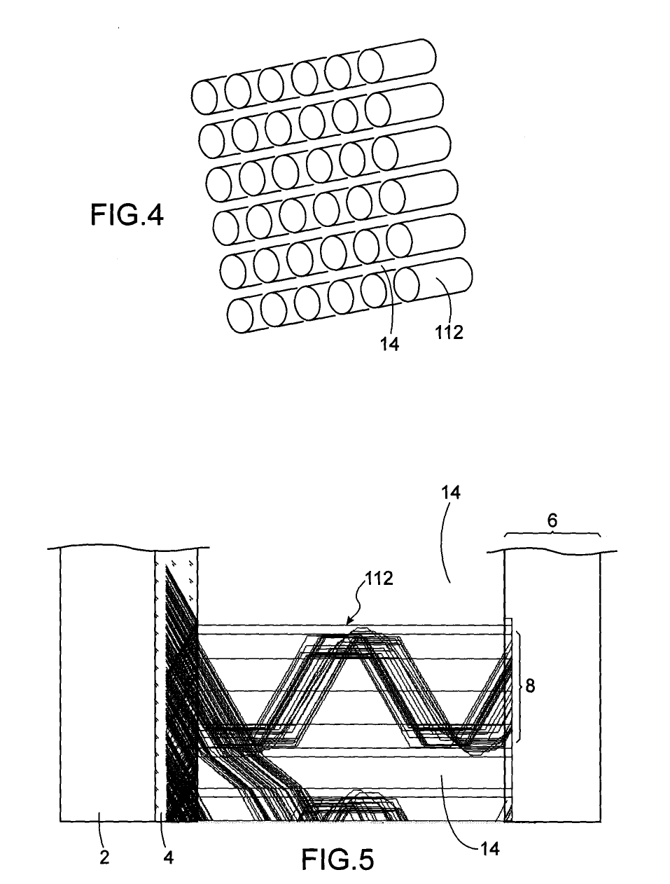

In FIG. 4, a particularly advantageous embodiment of portions made from a first material 12 can be seen. In this example, a portion made from a first material 12 is dedicated to each photodetector 8. The portions made from the first material 12 are in the form of a column with a circular cross-section extending between the substrate 2 and the photodetector 8. The columns are separated from one another by the second material, which is advantageously air.

The surface area of the cross-section of each column is substantially equal to the surface area of a photodetector.

Preferably, the bottom surface of the pad (in the representation in FIG. 1), that is to say the surface intended to be put in contact with the photodetector, corresponds to the active surface of the latter, or is inscribed in the latter, while the top surface may be rectangular, so that the surface collecting the photons emerging from the detector block is optimised.

The smaller the number of photodetectors per portion made from a first material, until a single photodetector per portion made from a first material as shown in FIG. 4 is reached, the more the spatial resolution of the imager is improved. This is because, the more the cross-section of the portions made from a first material that form light guides approaches the surface of a photodetector, the more the area collecting the visible photons produced in the detector from ionising photons is close to the area generating these visible photons, considering a direction perpendicular to the stacking of the detection block.

In this example, a pixel comprises 64 photodetectors, in the embodiment in FIG. 4, and 64 portions made from the first material in the form of a column are then formed.

FIG. 5 shows schematically the effect of the light guides on the travel of light rays emitted in the detector that is situated to the left in the representation in FIG. 4. It can be seen that the light rays undergo multiple reflections at the interface between the first material and the second material because of the choice of the optical indices, which has the effect of guiding the light rays R in the light guides as far as the active part of the photodetectors, rather than on the electronic part, which therefore increases the quantity of light collected by the active parts. It can be seen that, the larger the number of waveguides and the more it approaches the number of photodetectors, the more improved is the spatial resolution.

An imager may comprise certain photodetectors not covered by a portion made from a first material does not depart from the scope of the present invention.

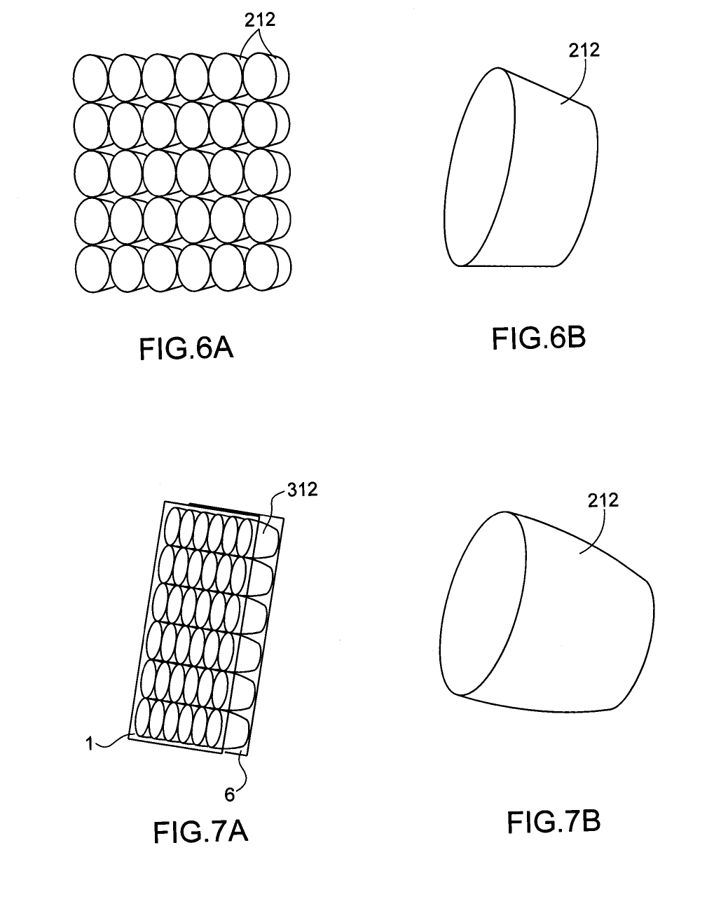

In FIGS. 6A and 6B, another example of advantageous embodiments of portions made from a first material 12 in FIG. 4 can be seen. The portions made from a first material 12 have the form of a truncated cone, the large base being oriented on the side of the detector. The portions may have other forms, and this whatever the embodiment. It may for example be a case of a pyramid with a square cross-section, or a pyramid with a truncated square section, or a hemisphere.

For the case of the detection of photons at a small angle, it was found that the pads where the cross-section decreases, between the detector block and the matrix of photodetectors, made it possible to increase the collection efficiency. Thus, in this case, the pads formed so that their base, that is to say the surface in contact with the detector block, is wider than their end in contact with the photodetector, are preferred. Straight pads, i.e. with a constant transverse section, can be used for detection at higher angles. The foot of glue 14 in the case of photons with a small angle and with a greater angle rectify the beams towards the detection area.

The height of the pads, that is to say the distance separating the photodetectors from the detector block, may vary, for example, between 1 μm and 100 μm, preferably between 5 μm and 30 μm. The height of the pads, that is to say the distance separating the photodetectors from the detector block or the substrate (or the base of the pads from their end) may vary, for example between 1 μm and 100 μm, preferably between 5 μm and 30 μm.

The surface area of the small base (or their end) is preferably substantially equal to the surface area of the active part of a photodetector.

In FIGS. 7A and 7B, yet another example can be seen of an embodiment wherein the portions made from the first material 12 have the form of a paraboloid with a truncated bottom, the bottom with the smallest surface area being oriented on the same side as the reading block. The example embodiments in FIGS. 6A, 6B and 7A, 7B are particularly suited to the embodiment wherein a portion made from a first material is provided for each photodetector. The surface area of the truncated base is substantially equal to the surface area of the active part of a photodetector. However, an imager wherein the portions made from a first material cover more than one photodetector and have a frustoconical or parabolic shape do not depart from the scope of the present invention.

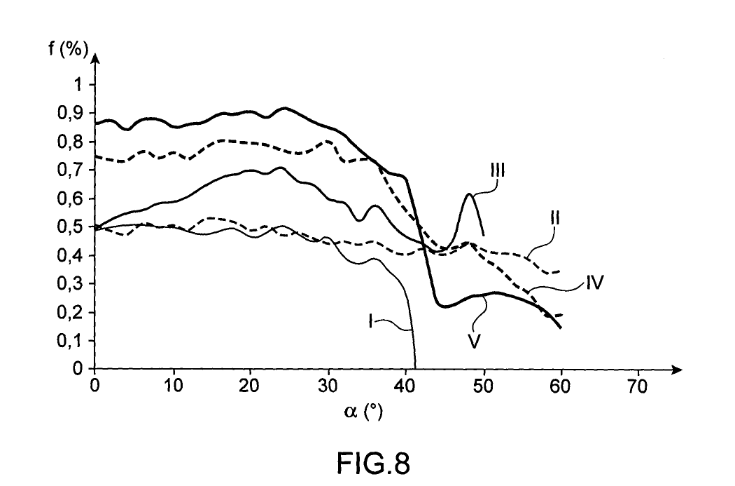

The example embodiments in FIGS. 6A, 6B and 7A, 7B have the advantage of allowing the collection of a quantity of light very much greater than that collected by the portions made from a first material in the form of a column as shown in FIG. 8.

Preferably, according to this embodiment, the pads are delimited by a second reflective material, for example a metal, or one with an index lower than that of the material of the pads, so that some of the photons emerging towards the outside of a pad are re-admitted in this pad. “Reflective” means a material for which the majority of the incident light is reflected rather than being absorbed or transmitted.

If a structure is considered wherein the first material of the pads is SiO₂ and the second material is copper or another metal; the photons are reflected: the guidance of the light is effected by reflection, because of the presence of metal, and therefore of the reflected material, at the interface between the first material and the second material. When the radiation is in the visible range, metals, and for example copper, are good reflectors.

In FIG. 8, a graphical representation can be seen of the fraction f as a % of the light collected by a pixel according to the angle of incidence α (°) for various structures.

A Lambertian emitter in an infinite medium of index 1.51 is considered, which is formed by the detector 2 and the substrate 4. The first material is a glue of index 1.51. The detector block and the photodetection block are separated by a distance of 10 μm. As a reminder, the detector block comprises the scintillator material, the latter being able to be mechanically supported by a layer of transparent material, for example glass.

The curve I represents the case where the layer of air separates the substrate 4 from the photodetectors.

The curve II represents the fraction of light collected by one pixel in the case where the entire pixel is covered with glue, which corresponds to the imager in FIGS. 1 to 3.

The curve III represents the fraction of light collected by the device in FIG. 4, comprising a portion made from the first material in the form of a column for each photodetector.

The curve IV represents the fraction of light collected by the device in FIG. 6.

The curve V represents the fraction of light collected by the device in FIG. 7.

In all cases, the fill factor of the matrix of the photodetectors is 50%. Thus it is found with curve I that the fraction of light collected in normal incidence is equal to the fill factor of the sensor. This falls for an angle greater than 33°, this angle corresponding to the total internal reflection angle.

The curve II shows the fraction of light collected in the case where several photodetectors are covered by the same first material.

It is found that, because of the variation in the total internal reflection angle at the interface between detector block and air, there is more light collected by the matrix of photodetectors. For example, a beam emerging from the detector block at an angle greater than the total reflection angle, with respect to the vertical, is not re-emitted to the detector when the first material is air; the total reflection angle is around 33.3° considering that the index of the scintillator is 1.82. On the other hand, when the air is replaced with adhesive resin, the index of which is higher than the index of air, the total reflection angle increases. Thus the quantity of light collected by the elementary photodetectors making up the matrix is increased. The sensitivity of the device is then increased.

The curve III shows that the fraction of the light collected increases substantially for angles around 20° passing from 50% to 70%, which is obtained by means of the guidance of the light by the columns.

It is also found that the fraction of light collected by the devices in FIGS. 6 and 7 (curves IV and V) is further increased compared with that of the device in FIG. 4. Furthermore, the curves IV and V show that the light is concentrated for small incident angles, typically less than 45°. In other words, the photons emitted by the detector at such angles are channelled by the light guide, formed by the pads produced in the first material, surrounded by a second material the index of which is lower. A similar result would be obtained by disposing a reflective material at the periphery of each pad.

Thus not only does the structure substantially increase the resolution in terms of energy, by increasing the quantity of light collected, but also substantially improves the spatial resolution of the conversion point of the gamma or X-ray photon into a visible photon, the light being collected at small angles. The addition of rectifying areas 14 at the end of the pads further increases the quantity of light collected.

The portions made from a first material may be deposited either only on the photodetectors, for example patterns from a few microns to a few hundreds of microns depending on the size of the photodetector, or on a set of photodetectors in order to mask an electronic part situated alongside these photodiodes, routing, etc., and the patterns may then be from a few hundreds of μm to a few mm.

Furthermore, in the case where each portion made from a first material covers only one photodetector, it may have a form other than a column with a circular cross-section and may be a column with a square cross-section, for example with sides of 12 μm.

By way of example, the first material may be a SU8 resin or a resin of the EPO-TEK®353ND, EPO-TEK®360ND, polycarbonate, SiO₂, etc. type.

In the case where the second material is a reflective material, a metal may be chosen, for example copper with an index N=0.95, or aluminium.

By way of example, a detector according to this second embodiment can be implemented as follows:
a deposition of an oxide (SiO₂) is effected with a thickness of between 100 nm and 10 μm, preferably between 100 nm and 2 μm, or even 10 μm, on a substrate,
lithography then takes place in order to define areas to be etched,
an etching is then effected throughout the thickness of SiO₂, so as to emerge on the photodetectors, and the resin is removed, for example by chemical stripping for example,
the parts left free by the etching are then filled with a reflective material, preferably a metal, for example aluminium or copper,
a polishing is carried out so as to remove the residue of metal on the ends of the pads. Thus SiO₂ pads delimited by a metal are available,
next a layer of third material is deposited on the reading block and the substrate provided with the pads and the reading block are assembled, thus forming areas 14 of third material wetting the end of the pads.

According to a variant, the deposition of a metal layer can also be effected before carrying out lithography, the spaces left free by the lithography being filled in by means of a first material.

The guides thus described can be applied to types of images other than to ionising radiation images, such as for example infrared or UV imagers or wavelength shifters.

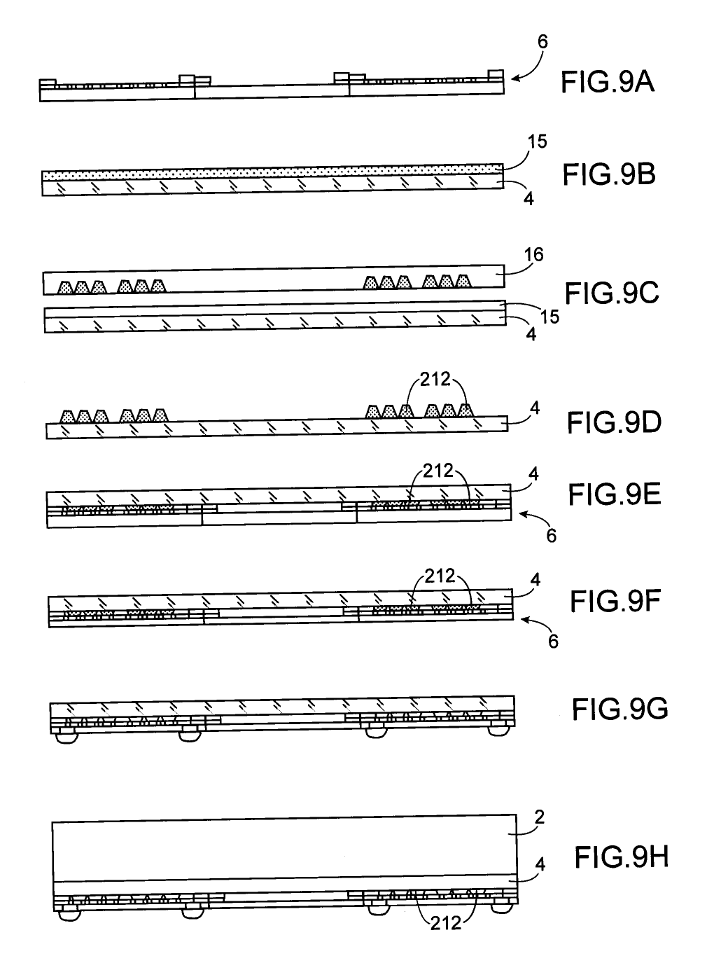

We shall now describe various embodiments of a method for producing an imager according to the present invention in the case where the portions made from a first material have a frustoconical shape, the steps of which are shown schematically in FIGS. 9A to 9F.

Firstly the reading block is produced, which is formed from a substrate comprising matrices of photodetector pixels. The reading block without its electrical connections, which will be produced subsequently by vias, is shown in FIG. 9A.

Moreover, a layer of thermoplastic or thermosetting or UV-setting polymer is formed on a glass substrate 4. For example, it may be a thermoplastic such as PMMA or PS and/or a UV-setting polymer such as the SU8 resin manufactured by the company MicroChem®, for example by spin coating.

Alignment crosses were produced in advance on the glass substrate 4 for aligning the substrate with a mould 16. The mould 16 comprises a plurality of frustoconical recesses corresponding to the shape of the portions made from a first material 12. The truncated cone is in contact with the glass substrate 4.

The element thus obtained is shown in FIG. 9B.

During a following step, preferably the mould and the substrate comprising the layer of resin are heated before the pressing step, at a temperature higher than the glass transition temperature of the polymer, typically 20° to 50° above the glass transition temperature of the polymer. The mould 16 is aligned with the substrate 2 (FIG. 9C) and next the resin is impressed by means of the mould 16 (a step also referred to as imprint). The mould is next pressed in the polymer film, which fills the mould cavities. For example, the pressure is between a few bar and 40 bar. Finally, the mould and the substrate are cooled to a temperature below the glass transition temperature and then separated. The element obtained after removal of the mould is shown in FIG. 9D.

For example, if the pads are produced in SU-8, which is a UV-setting resin, after imprinting, the SU-8 pads are exposed to UV radiation and annealed in order to finalise the hardening of the resin.

During a following step, a layer of a third material is deposited on the reading block, for example by spin coating. Let h be the height of the pads, the thickness of the layer of glue is then advantageously between h/10 and 3h/4.

For example, h is equal to 4 μm and the thickness of the glue is between 100 nm and 3 μm.

During the following step, the element obtained after imprinting is turned over and is aligned with the reading block provided with the layer of third material; more particularly each portion made from a first material is aligned with the active part of a photodetector so that each pad 12 is centred on a photodetector. During this application, each pad 12 penetrates the layer of third material 13, the thickness of which is such that the third material 13, which is adhesive, wets the walls of each pad 12 and forms an area 14 surrounding each end of a pad 13.

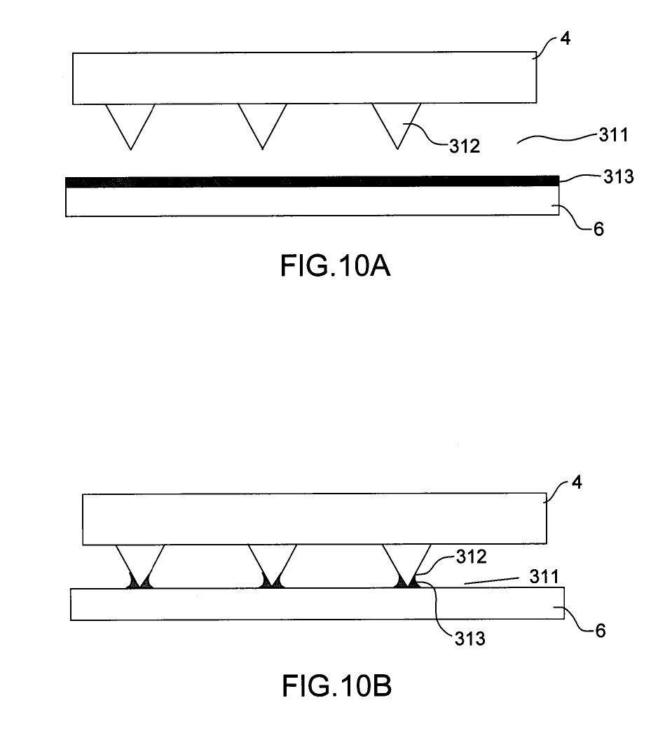

The gluing is then carried out. The portions of resin are then in contact with the glass substrate 2 and the photodetectors 8. In FIG. 10A the element provided with the pads and the reading block covered with the layer before assembly can be seen shown.

The element obtained is shown in FIG. 9E. In FIG. 10B, the element provided with the pads and the reading block covered with the layer after assembly can be seen in detail, and the ends of the pads 12 oriented towards the reading block 6 are wetted by the glue.

Next a step of thinning the substrate of the reading block takes place, for example by polishing, this is for example made from silicon. The mechanical rigidity of the assembly is provided mainly by the glass substrate 4.

The element obtained is shown in FIG. 9F.

The electrical connections of the reading block to the vertical connection means or via (or TSV “through-silicon via”) are then made through the substrate and connection balls. The element obtained is shown in FIG. 9G.

Next the detector 2 is connected to the element shown in FIG. 9G. The imager thus obtained is shown in FIG. 9H.

According to this embodiment, the second material 11 may be air.

FIGS. 11A and 11B, a detail view of a pad 12 can be seen before and after assembly respectively, and in FIG. 11B the area 14 can be seen enlarged.

In FIG. 14, a photograph of a pad 12, the layer of third material 13 and a rectifying area 14 obtained by means of the method according to the invention can be seen.

The use of a mould makes it possible to produce portions of resin with a free shape, for example pads not having a constant cross-section, for example in the form of truncated lenses, truncated cones (FIG. 6), or parabolas (FIG. 7). As explained previously, these shapes are particularly advantageous as a background.

We shall now describe another embodiment of the production method according to the invention.

This method differs from the one described with reference to FIGS. 9A to 9H in that, after the step of coating the substrate, lithography is carried out. For this the resin is insolated through a mask, defining the portions of resin in the glue. Next the insolated areas are developed; for this a low-temperature annealing is carried out in order to activate the polymerisation, and then a chemical attack is carried out in order to remove the parts of the resin that have been insolated. For this, a usual resin is JSR M78Y, a thickness of which of between 500 nm and 1 μm is deposited with a spinner (referred to as “spin coating”). The resin is then annealed for a first time at 130° C. in order to eliminate the solvents. After insolation, the resin is heated for a second time at the same temperature in order to be hardened. The developer used is TMAH (tetramethylammonium hydroxide).

This method is not a contact lithography, unlike the imprinting method. The forms of the pads that can be produced are forms with a constant cross-section, such as those in FIGS. 3A to 3B and FIG. 4 or with a slight slope as will be described below.

The production of the areas 14 also makes it possible to produce a stronger assembly of the pads on the substrate carrying the photodetectors because of the presence of a relatively great thickness of the glue 13 and therefore to obtain a more robust device. This production method is therefore all the more advantageous when the first material constituting the pads is not sufficiently adhesive, and then a third material is used, the refractive index of which is close to that of the first material. This third material is adhesive, so that it affords good adhesion between the pads and the matrix of photodetectors.

In FIG. 11C, an example of pads in the form of a truncated pyramid can be seen. It is also possible to produce rectification areas as for a pyramid-shaped pad or pads in the form of truncated paraboloids.

In FIGS. 12A and 12B, the pad is in the form of a cylinder. A rectification area 14 is also formed around the pad.

The pads in a pyramidal, truncated pyramid and truncated paraboloid form are produced by imprinting. The pads of cylindrical form can be produced by imprinting or by UV lithography as described previously.

In general, according to this embodiment, the pads extend between a top base and a bottom base, the bottom base being up against the photodetector; the transfer section of said pads increases over the bottom part of the pads, that is to say on the part adjacent to the bottom base.

The imprinting technique is particularly suited for structuring non-conventional substrates in microelectronics, such as for example substrates of the scintillator type.

A method for producing a mould for imprinting will now be described briefly.

A hard mask is deposited on a substrate, for example made from silicon, provided with alignment marks. This is then structured by the deposition of a resin forming a pattern on the mask and by mask etching.

The silicon is then etched through the mask and the mask is removed. This is wet or dry etching or a combination of the two.

Preferably the mould thus formed is covered with a layer having non-adhesive properties, for example a single layer of molecules containing fluorinated atoms. This type of treatment is well known to persons skilled in the art and will not be described in detail. Such a layer facilitates the separation from the mould and from the substrate after imprinting.

In the case where the pads are produced on the detector block, they are assembled with the photodetectors, preferably with a machine of the flip-chip type, which enables the waveguides to be aligned with the photodetectors. An alignment of less than 1 μm can be achieved for aligning the waveguides with a photodetector substrate.

The form of the rectification areas 14 can advantageously be controlled during the gluing. For example, control of the time, the gluing temperature, the surface energies of the waveguides and the thickness of the glue makes it possible to control the form of the rectification areas 313.

The choice of the temperature of the third material, during pressurisation, has an effect on its viscosity. The higher the temperature, the more viscous the third material, and in addition this has a tendency to rise along the pads and therefore to wet them further. Controlling the temperature of the third material controls the wettability of the third material. The wetter the pads, the more pronounced is the beam rectification effect.

For example, in the case where the layer 313 is made from SU8, by pressing pyramidal waveguides with a slope of 80° at a temperature 50° higher than the glass transition temperature of the SU8 resin and at a temperature 10° higher than the glass transition temperature of the SU8 resin, rectification areas with very different forms are obtained. The areas obtained at a temperature 50° higher than the glass transition temperature of the resin has a greater height along the pads than that obtained with a temperature 10° higher than the glass transition temperature.

It is also possible to greatly accentuate the forms of the rectification area 14 by controlling the surface energy of the waveguides and controlling the height at which the third material wets the pads by modifying the wetting angle of the third material on the pads. For this purpose, chemical treatments are applied to the surface of the pads. These treatments are aimed at modifying the hydrophilic or hydrophobic character of the pads, by hydrophobic treatments, for example of the OpTool® type, or hydrophilic treatments, for example of the plasma argon or plasma argon and acetic acid vapour type.

Like the control of the temperature of the third material by promoting the wetting of the pads by the third material by virtue of suitable surface treatment, it is possible to amplify the effect of rectification of the beams.

As described above, the cylindrical waveguides can be produced by photolithography. It is also possible to produce waveguides in the form of cones with a slight slope. For this purpose, a substrate 4 is for example coated with a photosensitive resin, for example JR 335 resin. Next, by controlling the doses and the focusing distances, it is possible to obtain various types of structure having a slight slope, as presented in FIGS. 13A and 13B.

After development of the non-exposed areas, the scintillator block is assembled on the waveguides.

In FIG. 13A, the pad with a roughly cylindrical shape 12.1 has a concave lateral edge and in FIG. 13C the pad 12.3 has the form of a truncated cone with a slight slope, that is to say with a slope of less than 20°. The dose is around 300 mJ/cm² and the defocusing may vary from −10 μm to 10 μm.

By way of example, the transparent or silicon substrate is coated with a 3 μm layer of JR 355. The latter undergoes UV lithography. The resin not exposed by the UV radiation is then developed.

1-22. (canceled)

23. A radiation imager comprising:
a reading block configured to convert radiation into an electrical signal, comprising a plurality of photodetectors;
a first substrate;
a plurality of portions made from a first material with a first optical index extending between the first substrate and the reading block;
a second material at a periphery of at least one of the portions, the second material having a second optical index lower than the first optical index, or being a reflective material;
at least one area made from a third material surrounding at least one of the portions made from a first material at an end of the portion made from a first material oriented on a same side as the reading block, the at least one area made from a third material obtained by applying a layer made from a third material to the reading block and penetrating the end of the at least one portion made from a first material in the layer made from a third material.

24. The radiation imager according to claim 23, wherein each portion made from a first material is surrounded by an area made from a third material at its end oriented on the same side as the reading block.

25. The radiation imager according to claim 23, wherein the first substrate is a transparent material, or is glass.

26. The radiation imager according to claim 23, wherein the first substrate is a detector block, comprising at least one detector configured to emit an optical signal from an incident radiation to be imaged.

27. The radiation imager according to claim 23, wherein the optical index of the third material is greater than or equal to that of the second material.

28. A method for producing a radiation imager according to claim 23, including a reading block configured to convert the radiation into an electrical signal, including a plurality of photodetectors, the method comprising:
a) forming a plurality of portions of a first material, with a first index, on a first substrate, the portions comprising, at a periphery thereof, a second material, the second material having a second optical index lower than the first optical index or being a reflective material;
b) forming a flat layer made from a third material on the reading block;
c) aligning the first substrate with respect to the reading block, so that the portions formed on the detector block are disposed opposite the photodetectors of the reading block;
d) assembling the substrate and the reading block by the portions made from a first material, so that the third material is wetted on the portions of the first substrate;
e) hardening the third material.

29. The method for producing a radiation imager according to claim 28, wherein a) comprises:
forming a layer made from a first material on the first substrate, the first material being a resin;
placing a mold including cavities having the external shape of the portions made from a first material above the layer made from a first material;
pressing first material by the mold;
heating the first material above a glass transition temperature of the first material;
cooling the first material below the glass transition temperature, and then removal from the mold.

30. The method for producing a radiation imager according to claim 28, wherein a) comprises:
forming a layer of the first material on the first substrate, the first material being a resin;
insolating the first material through a mask defining the portions made from the first material;
activating polymerization by low-temperature annealing;
removing parts of the first material that were insolated.

31. The method according to claim 28, wherein, during b), the thickness of the layer made from a third material is between h/10 and 3/h/4, h being height of the portions made from a first material.

32. The method according to claim 31, wherein a thickness of the layer made from a third material is between 100 nm and 3 μm.

33. The method according to claim 28, wherein the first material is an SU8 resin or a resin of EPOTEK353ND, EPOTEK360ND, or polycarbonate type.

34. The method according to claim 28, wherein the first material has an index close to that of the material of the detector, or is between 1.4 and 3.

35. The method according to claim 29, wherein the cavities of the mold have a shape of revolution or polygonal.

36. The method according to claim 35, wherein the cavities of the mold have a variable cross-section reducing as from the face wherein they emerge.

37. The method according to claim 29, wherein the mold and the substrate comprising the layer of resin are heated before the pressing.

38. The method according to claim 28, wherein the first substrate is a transparent material, or is glass.

39. The method according to claim 38, further comprising producing a detector block on the substrate, after assembly of the substrate and the reading block.

40. The method according to claim 28, wherein the first substrate is a detector block, comprising at least one detector configure to emit an optical signal from an incident radiation to be imaged.

41. The method according to claim 28, wherein, at least during d), temperature of the third material is adjusted so as to control wetting of the portions made from a first material.

42. The method according to claim 28, further comprising surface treatment of the portions to modify surface energy thereof.

43. The method according to claim 28, wherein deposition of the layer of the first material is carried out by centrifugal coating.

44. The method according to claim 28, further comprising producing a via and connection by metal balls.
